(19) United States
(12) Patent Application Publication
(10) Pub. No.: US 2012/0188720 A1
(43) Pub. Date: Jul. 26, 2012

(54) HEAT DISSIPATING STRUCTURE FOR HEATING ELEMENT

(75) Inventors: Takahiro Okuie, Nara-shi (JP); Masahiko Takada, Hirakata-shi (JP)

(73) Assignee: SANYO ELECTRIC CO., LTD., Osaka (JP)

(21) Appl. No.: 13/355,310

(22) Filed: Jan. 20, 2012

(30) Foreign Application Priority Data
Jan. 21, 2011 (JP) 2011-011148

(51) Int. Cl. H05K 7/20

(52) U.S. Cl. 361/704

(57) ABSTRACT

A heat dissipating structure for heating element includes a heating element having a heat generating element for generating heat by being driven, and a first plate member and a second plate member bonded to one surface of the heating element so as to be stacked together. The first plate member has a cutout portion opened to penetrate therethrough and is bonded to the heating element so as to block the cutout portion, the second plate member has a protruding portion fitted to the cutout portion of the first plate member, the protruding portion being structured to penetrate through the cutout portion to be bonded to the heating element, and a modulus of longitudinal elasticity of a material constituting the first plate member is larger than a modulus of longitudinal elasticity of a material constituting the second plate member.

### CROSS-REFERENCE TO RELATED APPLICATION

This application is based upon and claims the benefit of priority of the prior Japanese Patent Application No. 2011-11148, filed on Jan. 21, 2011, the entire contents of which are incorporated herein by reference.

### BACKGROUND OF THE INVENTION

1. Field of the Invention

The present invention relates to a heat dissipating structure for dissipating heat generated by a heat generating element such as a CMOS imaging element or a CCD imaging element that generates heat by being driven.

2. Description of the Related Art

According to an imaging apparatus having a function of compensating for degradation of a picked up image caused by camera shake, an imaging element such as a CMOS imaging element or a CCD imaging element is fitted to a camera shake correction unit and swingably arranged in a plane orthogonal to an optical axis of an image pickup lens. When a fitting structure of the imaging apparatus becomes heavy, the camera shake also adversely affects a camera shake correction function. Accordingly, it is preferable that the fitting structure be as light as possible.

In addition, according to the above-mentioned imaging element, in particular, the CMOS imaging element, since a noise in an image signal increases as a temperature increases, it is necessary to devise a way for efficiently dissipating heat caused by driving from the imaging element.

In view of the above, there is proposed an imaging apparatus in which an imaging element is bonded to a heat sink formed of an aluminum plate which is light and has excellent thermal conductivity, and the heat sink is screwed to a movable plate of a camera shake correction mechanism.

A light-receiving portion or a light-receiving surface of an imaging element should be arranged vertically with respect to an optical axis of an image pickup lens of the imaging apparatus. However, rigidity of aluminum is low (i.e., a modulus of transverse elasticity is small), and a Young's modulus (modulus of longitudinal elasticity) thereof is also small. For this reason, when the imaging element is fitted using the heat sink made of aluminum as described in Patent Document 1, there is a high probability that the heat sink is deformed, and therefore an orientation or a posture of the imaging element deviates with respect to the optical axis.

### SUMMARY OF THE INVENTION

A heat dissipating structure for heating element according to the present invention includes a heating element having a heat generating element for generating heat by being driven, and a first plate member and a second plate member bonded to one surface of the heating element so as to be stacked together. The first plate member has a cutout portion opened to penetrate therethrough and is bonded to the heating element so as to block the cutout portion, the second plate member has a protruding portion fitted to the cutout portion of the first plate member, the protruding portion being structured to penetrate through the cutout portion to be bonded to the heating element, and a modulus of longitudinal elasticity of a material constituting the first plate member is larger than a modulus of longitudinal elasticity of a material constituting the second plate member.

According to the heat dissipating structure for heating element of the present invention, it is preferable that a specific gravity of the material constituting the second plate member be smaller than a specific gravity of the material constituting the first plate member.

Further, according to the heat dissipating structure for heating element of the present invention, it is preferable that thermal conductivity of the material constituting the second plate member be lower than thermal conductivity of the material constituting the first plate member.

### BRIEF DESCRIPTION OF THE DRAWINGS

FIG. 1 is a front view of a heat dissipating structure for heating element according to an embodiment of the present invention;

FIG. 2 is a rear view of the heat dissipating structure for heating element according to the embodiment of the present invention;

FIG. 3 is a side view of the heat dissipating structure for heating element according to the embodiment of the present invention;

FIG. 4 is a top view of the heat dissipating structure for heating element according to the embodiment of the present invention;

FIG. 5 is an exploded perspective view of the heat dissipating structure for heating element according to the embodiment of the present invention; and

FIG. 6 is a perspective view of a camera shake correction unit illustrating how the heat dissipating structure for heating element according to the embodiment of the present invention is fitted.

### DETAILED DESCRIPTION OF THE PREFERRED EMBODIMENTS

Hereinafter, an embodiment of the present invention will be described with reference to the drawings. FIG. 1 to FIG. 5 illustrate a heat dissipating structure 11 for heating element according to one embodiment of the present invention. The heating element may be structured of an imaging element 13 which is a heat generating element generating heat by being driven and has a substantially rectangular shape, and a board 15 fitted to the imaging element 13. The heat dissipating structure 11 is provided with a first plate member 31 and a second plate member 51 made of metal and to be bonded to the heating element.

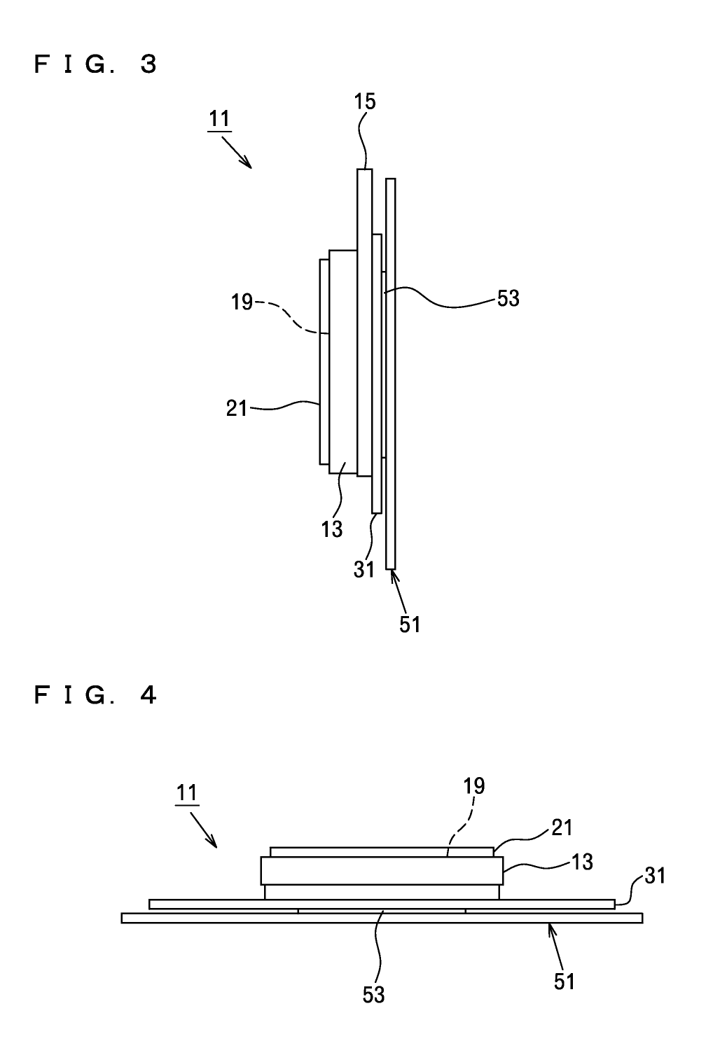

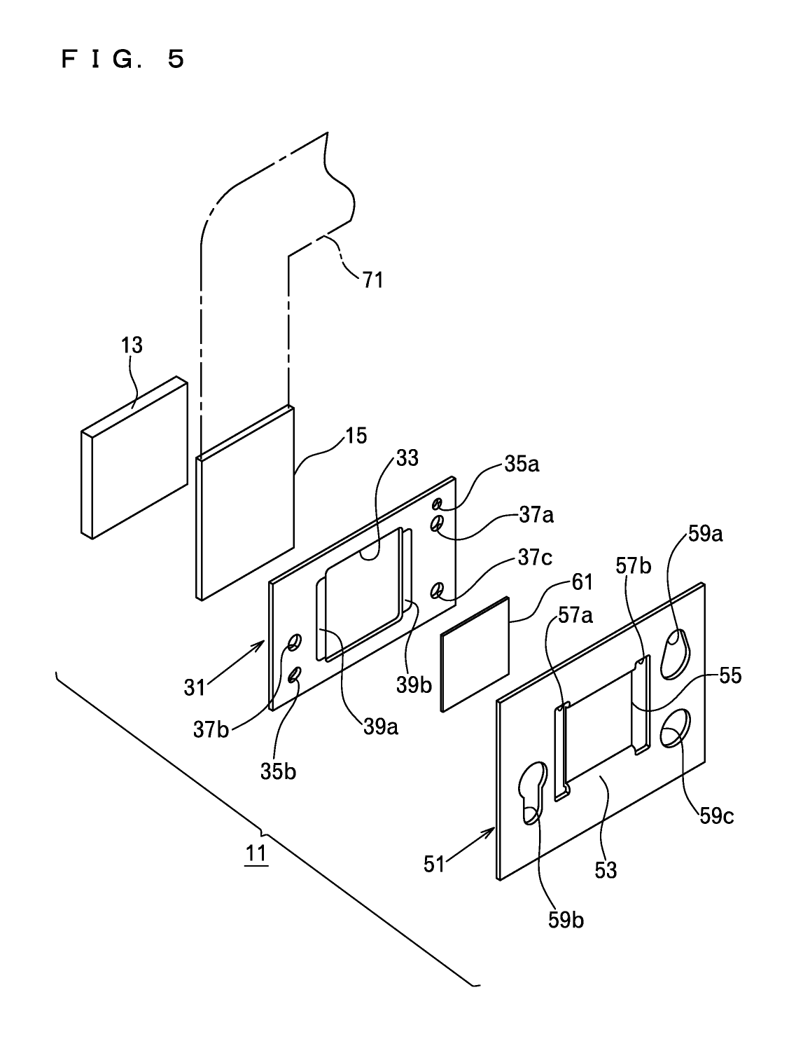

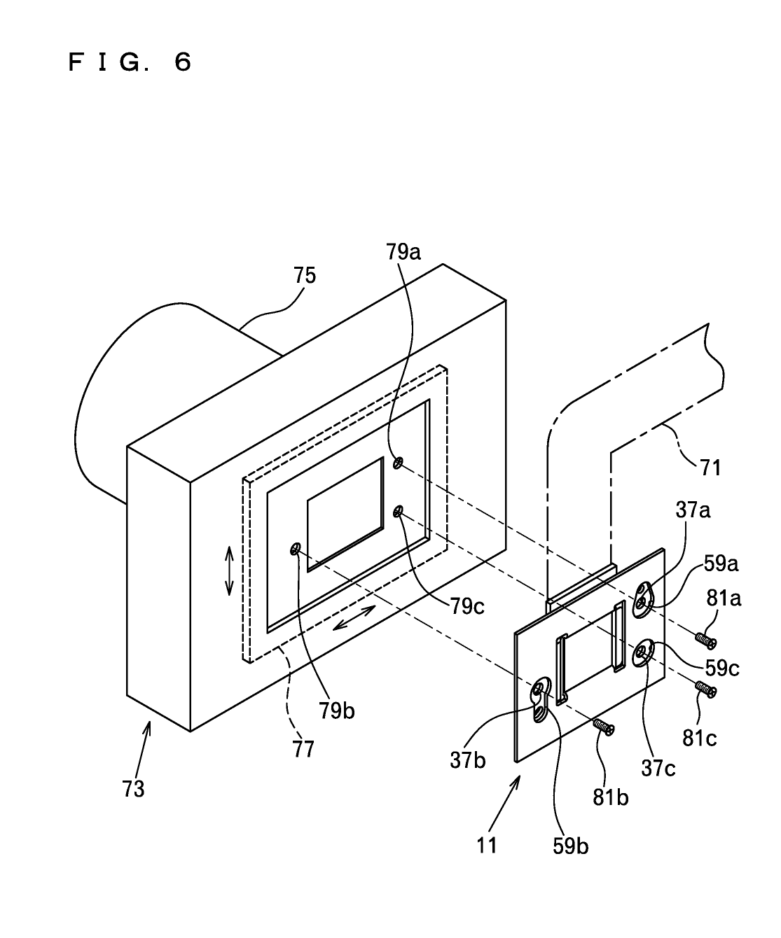

The imaging element 13 that generates heat by being driven can be exemplified by a CMOS imaging element or a CCD imaging element, and includes a light-receiving portion 19 arranged in a recess 17 having a rectangular shape and formed in a substantially center, as illustrated in FIG. 1. As illustrated in FIG. 3 and FIG. 4, a protective glass plate 21 is fitted in the recess 17 so as to cover the light-receiving portion 19. The board 15 having a substantially rectangular shape is an electronic circuit board and for example, a rigid board such as a glass epoxy board or a ceramic board may be used as a board material. The board 15 is larger than the imaging element 13, and a length of the board 15 in a shorter direction is almost the same as a length of the imaging element 13 in a longer direction in this embodiment. The imaging element 13 is arranged on a front side of the board 15 such that an end portion of the board 15 extends from one edge along the longer direction of the board 15. One end of a flexible board 71 having a band shape is connected to the extended end portion of the board 15 (see FIG. 5 and FIG. 6). The other end of the flexible board 71 is connected to a circuit board provided with a signal processing circuit for processing an output signal from the imaging element 13 (not illustrated).

As illustrated in FIG. 3 and FIG. 4, a back side of the board 15 makes contact with the first plate member 31 on one surface (hereinafter, referred to as “first surface”) of the first plate member 31 having a substantially rectangular shape. As illustrated in FIG. 1, FIG. 3, and the like, the length of the first plate member 31 in a shorter direction is arranged to be longer than the length of the imaging element 13 in a shorter direction and nearly the same as the length of the board 15 in a longer direction. The length of the first plate member 31 in a longer direction is arranged to be longer than the length of the imaging element 13 in a longer direction or the length of the board 15 in a shorter direction, which is about twice the length thereof.

In this embodiment, the board 15 and the first plate member 31 are bonded together using an adhesive. The details thereof will be described later.

As illustrated in FIG. 5, a cutout portion 33 having a substantially rectangular shape and penetrating through the first plate member 31 is opened in a substantially center of the first plate member 31. In this embodiment, the cutout portion 33 is an opening like a window of a substantially square shape. Each side of the cutout portion 33 is arranged to be slightly shorter than the length of the board 15 in a shorter direction.

The cutout portion 33 is not limited to the exemplified window-shaped opening, but maybe a cutout opened in one direction or in two directions perpendicular to each other of peripheral edges of the first plate member 31.

As illustrated in FIG. 1, the board 15 is arranged so to block the cutout portion 33, and the imaging element 13 is placed above the cutout portion 33 with the board 15 interposed therebetween. The end portion of the board 15 to which the flexible board 71 is connected extends from one edge of the first plate member 31 in a longer direction thereof. In this embodiment, projection portions 39a, 39b having slight protrusions on the first surface of the first plate member 31 and recesses on the other surface (hereinafter, referred to as “second surface”) of the first plate member 31 are formed in a band shape on both edges of the cutout portion 33 along a shorter direction of the first plate member 31. In this embodiment, the back side of the board 15 makes contact with the projection portions 39a, 39b on the first surface side of the first plate member 31.

As illustrated in FIG. 1 and FIG. 5, positioning holes 35a, 35b are individually formed on two corners on a diagonal line of the first plate member 31, and screw insertion holes 37a, 37b are formed near the positioning holes 35a, 35b, respectively. Further, a screw insertion hole 37c is also formed on one of the remaining corners.

The second plate member 51 having a substantially rectangular shape has a size larger than that of the first plate member 31, and a protruding portion 53 protruding toward one surface (hereinafter, referred to as “first surface”) of the second plate member 51 is formed in a substantially center thereof. The protruding portion 53 has a top portion 55 having a substantially rectangular shape and parallel to the first surface of the second plate member 51. The top portion 55 is distanced from the first surface of the second plate member 51 by about a thickness of the first plate member 31, and is formed in a size slightly smaller than a size of the cutout portion 33 of the first plate member 31. Further, slits 57a, 57b are opened in the second plate member 51 on both sides of the protruding portion 53 along a shorter direction of the second plate member 51.

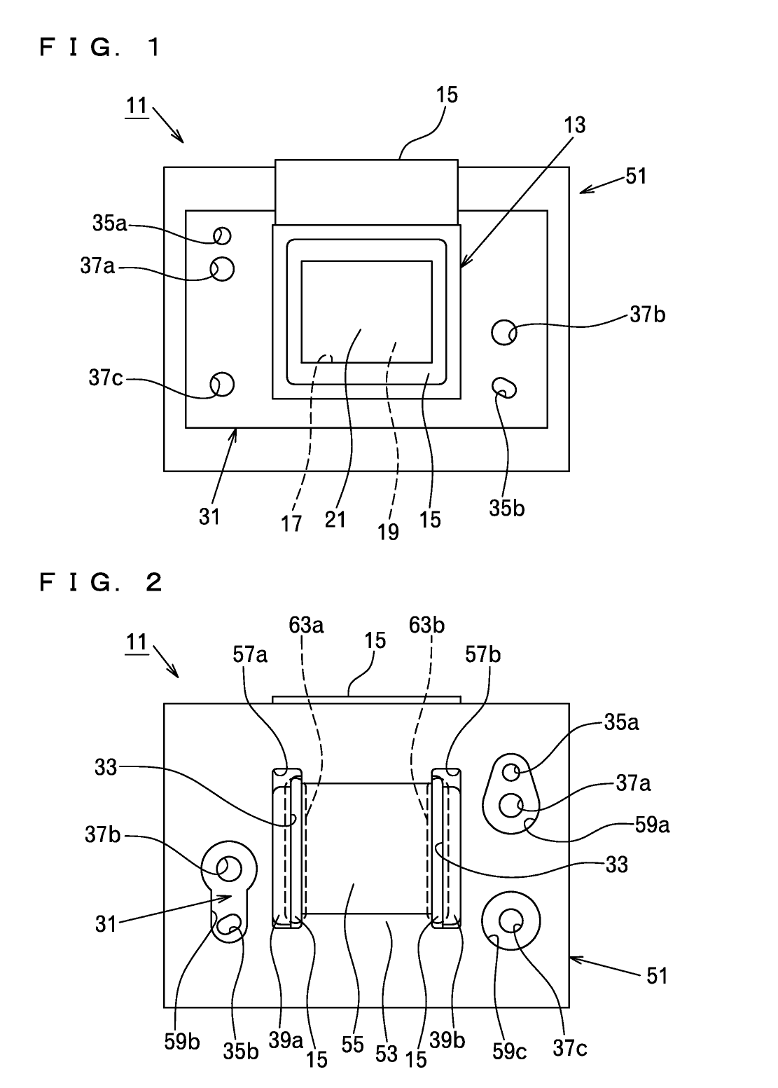

As illustrated in FIG. 2 and FIG. 5, two through-holes 59a, 59c are opened near one of edges along the shorter direction of the second plate member 51. One through-hole 59c of the two has a circular shape, and the other through-hole 59a has a teardrop shape such that the hole becomes smaller toward a corner of the second plate member 51. A through-hole 59b having a keyhole shape is formed near the other edge of the second plate member 51 along a shorter direction thereof. It is preferable that all of the through-holes 59a, 59b, 59c have sizes sufficient enough for accommodating therein heads of screws 81a, 81b, 81c for fitting, which will be described later, so that the heads of screws do not make contact with the through-holes.

The heat dissipating structure 11 for heating element according to this embodiment is formed, for example, in a manner described below. First, an adhesive is applied to the protruding portions 39a, 39b of the first plate member 31, and the first plate member 31 is positioned and adhered to the back side of the board 15 on which the imaging element 13 is fitted. During this process, since flatness of the imaging element 13 and the board 15 is important, the adhesion is carried out while sufficient flatness is secured.

Next, a thermally-conductive double-sided tape 61 having a substantially rectangular shape as illustrated in FIG. 5 is used to bond, together, the back side of the board 15 that is exposed from the cutout portion 33 of the first plate member 31 and the top portion 55 of the protruding portion 53 of the second plate member 51. During this process, as illustrated in FIG. 2, the second plate member 51 is positioned relative to the first plate member 31 so that the positioning hole 35a is exposed from the through-hole 59a of the second plate member 51, and the positioning hole 35b is exposed from the through-hole 59b of the second plate member 51. The through-holes 59a, 59b, 59c of the second plate member 51 are larger than the screw insertion holes 37a, 37b, 37c of the first plate member 31, and therefore the screw insertion holes 37a, 37b, 37c of the first plate member 31 are exposed from the through-holes 59a, 59b, 59c of the second plate member 51, respectively, by performing the positioning in this manner.

As illustrated in FIG. 2, both edges of the cutout portion 33 along a shorter direction of the first plate member 31 and dents of the protruding portions 39a, 39b are exposed from the slits 57a, 57b of the second plate member 51, respectively. Finally, an adhesive is coated in a build-up manner on the back side of the board 15 and in the dents of the protruding portions 39a, 39b along a shorter direction of the first plate member 31. As indicated by broken lines in FIG. 2, when adhesives 63a and 63b coated in a build-up manner are hardened, the board 15, the first plate member 31, and the second plate member 51 can be securely bonded together.

As illustrated in FIG. 6, the heat dissipating structure 11 for heating element produced according to the foregoing can be used by being fitted to a camera shake correction unit 73 of the imaging apparatus.

A lens unit 75 is provided on a front side of the camera shake correction unit 73, and light from the lens unit 75 is transmitted to the camera shake correction unit 73. The camera shake correction unit 73 is provided with a movable member 77 that is movable in two axial directions that are perpendicular to each other in a plane orthogonal to an optical axis of the lens unit 75, and camera shake can be compensated by moving the movable member 77 so as to cancel the camera shake detected by an angular velocity sensor or the like.

Three screw holes 79a, 79b, 79c are formed in the movable member 77 in a manner corresponding to the screw insertion holes 37a, 37b, 37c of the first plate member 31, respectively. The heat dissipating structure 11 is fixed to the movable member 77 by fixing the first plate member 31 to the movable member 77 with screws from a rear side of the camera shake correction unit 73. Screws 81a, 81b, 81c used for fixing are individually inserted through the insertion holes 59a, 59b, 59c of the second plate member 51 into the screw insertion holes 37a, 37b, 37c of the first plate member 31. Since heads of the screws 81a, 81b, 81c make direct contact with the second surface of the first plate member 31 without touching the second plate member 51, the second plate member 51 is not involved in fitting the imaging element 13. As a result, the second plate member 51 is not required to have such rigidity for fixing as required for the first plate member 51.

According to the heat dissipating structure 11 for heating element of this embodiment, since it is fitted to the camera shake correction unit 73 with the first plate member 31 interposed therebetween, it is necessary to choose, for the first plate member 31, a material having high rigidity and a modulus of longitudinal elasticity greater than that of a material for the second plate member 51.

Further, to achieve a light weight of the heat dissipating structure 11, a material having a specific gravity smaller than that of the material constituting the first plate member 31 is selected as a material constituting the second plate member 51 that is not involved in fitting the imaging element 13.

It is preferable to select materials which efficiently dissipate heat from the imaging element 13 as the materials for the first plate member 31 and the second plate member 51. In the case where thermal conductivity of the first plate member 31 is high, it is possible to increase heat dissipation performance of the heat dissipating structure 11 in its entirety as compared with a conventional case even if a material having low thermal conductivity is used for the second plate member 51, and therefore to effectively perform heat dissipation of the imaging element 13.

As a metallic material satisfying the above-mentioned requirements, if the material is selected from among, for example, copper, stainless steel, and aluminum, the moduli of longitudinal elasticity (Young's moduli) of copper, stainless steel (SUS304), and aluminum are about 130 GPa, about 197 GPa, and about 71 GPa, respectively. Therefore, it is possible to select a material other than aluminum from among these three metals as a material for the first plate member 31. Here, the moduli of transverse elasticity (moduli of elasticity in shear) of copper, stainless steel (SUS 304), and aluminum are about 48 GPa, about 74 GPa, and about 26 GPa, respectively. Therefore, it is preferable to use copper or stainless steel as a material for the first plate member 31 also in view of a large modulus of transverse elasticity.

In addition, the specific gravities of copper, stainless steel (SUS 304) , and aluminum are about 8.9 kgf/m³, about 7.9 kgf/m³, and about 2.7 kgf/m³, respectively. The thermal conductivities of copper, stainless steel (SUS 304), and aluminum are about 386 W/mK, about 17 W/mK, and about 204 W/mK, respectively. Accordingly, when the material is selected in view of heat dissipation effect and weight saving of the heat dissipating structure 11, aluminum is suitable among the three exemplified metals as a material for the second plate member 51.

The foregoing is an example of an optimum metallic material, and the present invention is not restricted to the above-mentioned metallic material. So far as the effect of the present invention can be obtained, it is possible to use an alloy of the above-mentioned metallic materials such as a copper alloy or an aluminum alloy, or alternatively use metallic materials or a combination thereof other than the above-mentioned materials to form the first plate member 31 and the second plate member 51. For example, titanium may also be used for the first plate member 31.

The first plate member 31 and the second plate member 51 can be produced by subjecting a plate of the above-mentioned metallic material to press work.

According to the above-mentioned embodiment, since the board 15 makes direct contact with the first plate member 31 made of a material having a large modulus of longitudinal elasticity, a deviation in the position or orientation of the imaging element 13 is suppressed. Using the first plate member 31 made of copper is preferable in terms of heat dissipation effect. It is also preferable to use the first plate member 31 made of stainless steel in terms of effect for suppressing positional deviation or the like of the imaging element 13. In any of the cases, it is possible, by using the second plate member 51 made of aluminum, to effectively perform heat dissipation of the imaging element 13 without excessively increasing the weight of the heat dissipating structure 11.

In the embodiment, the heating element is structured of a heat generating element (imaging element 13) that generates heat by being driven and the board 15, and the first plate member 31 and the second plate member 51 are fitted to the board 15. However, the heating element may be structured of a heat generating element alone, and the first plate member 31 and the second plate member 51 may be fitted to a portion other than the board 15.

Further, although the imaging element is exemplified as the heat generating element, the present invention can also be applied to a heat dissipating structure for heat generating element that generates heat by being driven other than the CMOS imaging element or the CCD imaging element, for example, a microprocessor, a power transistor, and the like.

The foregoing description is intended to illustrate the present invention, and should not be construed as limiting the invention specified in the claims or as restricting the scope of the invention. The configuration of each part of the invention is not limited to the foregoing embodiments, and modifications are possible within the technical scope of the invention specified in the claims.

What is claimed is:

1. A heat dissipating structure for heating element, comprising:
a heating element having a heat generating element for generating heat by being driven; and
a first plate member and a second plate member bonded to one surface of the heating element so as to be stacked together, wherein
the first plate member has a cutout portion opened to penetrate therethrough and is bonded to the heating element so as to block the cutout portion,
the second plate member has a protruding portion fitted to the cutout portion of the first plate member, the protruding portion being structured to penetrate through the cutout portion to be bonded to the heating element, and
a modulus of longitudinal elasticity of a material constituting the first plate member is larger than a modulus of longitudinal elasticity of a material constituting the second plate member.

2. The heat dissipating structure for heating element according to claim 1, wherein
the heating element is formed by fitting the heat generating element to a board, and the first plate member and the second plate member are bonded to the board.

3. The heat dissipating structure for heating element according to claim 1, wherein
the heat generating element is an imaging element and capable of being fitted to a camera shake correction unit of an imaging apparatus with the first plate member interposed therebetween.

4. The heat dissipating structure for heating element according to claim 1, wherein
a specific gravity of the material constituting the second plate member is smaller than a specific gravity of the material constituting the first plate member.

5. The heat dissipating structure for heating element according to claim 1, wherein
thermal conductivity of the material constituting the second plate member is lower than thermal conductivity of the material constituting the first plate member.

6. The heat dissipating structure for heating element according to claim 3, wherein
one or a plurality of screw insertion holes for fitting, with screws, the first plate member to the camera shake correction unit are formed in the first plate member, and one or a plurality of through-holes are opened in the second plate member at positions individually opposing the one or the plurality of screw insertion holes, and have diameters larger than the one or the plurality of screw insertion holes corresponding thereto so that heads of the screws for fitting can be individually inserted therethrough.

7. The heat dissipating structure for heating element according to claim 1, wherein
the first plate member is formed of copper, a copper alloy, or stainless steel, and the second plate member is formed of aluminum or an aluminum alloy.
